(19) United States
(12) Patent Application Publication
(10) Pub. No.: US 2023/0326444 A1
(43) Pub. Date: Oct. 12, 2023

(54) CAST COVER WITH INTEGRATED NOISE MITIGATION METHOD

(71) Applicant: GM GLOBAL TECHNOLOGY OPERATIONS LLC, Detriot, MI (US)

(72) Inventors: Anil K. SACHDEV, Rochester Hills, MI (US); Arianna T. Morales, Bloomfield Hills, MI (US); Song He, Troy, MI (US)

(21) Appl. No.: 17/718,964

(22) Filed: Apr. 12, 2022

(51) Int. Cl. G10K 11/168; B23P 15/00

(52) U.S. Cl. CPC G10K 11/168; B23P 15/00

(57) ABSTRACT

A cover for a housing includes a cast plate-like member having a top side and a bottom side with a plurality of raised ribs on the bottom side, the plurality of raised ribs defining a plurality of spaces therebetween. A noise insulating material is provided in at least some of the plurality of spaces. A sheet metal plate is adhered to a top of the plurality of raised ribs by an adhesive.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a cast cover for a housing with noise mitigation features.

Various vehicle systems are disposed within vehicle mounted housings. By way of non-limiting example, drive units for battery electrical automobiles and other engine driven components may use integrated power electronics (IPE) that are disposed within a housing. The vehicles include numerous components including engines, motors and gears that may transmit noise and vibration. The noise and vibrations can be transmitted to the various housings that may produce undesirable noise. In particular, this noise may be partially transmitted by a radiative cover of the housing. A reduced noise may improve passenger experience.

Machine components are often comprised of panel assemblies. In some industries, panel assemblies may be generally square or uniform in shape, whereas in other industries specific tailored shapes are desired for a panel assembly. In an automotive example, vehicle panel assemblies may include automotive features, such as a cover for an IPE, an inner panel for a door or a deck lid, a dash panel, a glove box door panel, front-of-trunk panel, a battery tray panel and other interior panels. To reduce the mass of the panel assemblies, a lighter density material may be used, or the cross sectional thickness of the panel assemblies may be reduced. Reducing the mass of the panel assemblies may facilitate reducing the overall weight of the machine as a whole. A reduction in the weight of a vehicle, for example, may provide increased efficiency that can be used beneficially in various ways. For example, a reduced weight may increase the range of an electronic vehicle, which may also be translated into cost savings on the battery pack of an electronic vehicle. Light weight metal panels with reduced thickness may have reduced stiffness and damping, and therefore may be an effective conduit for noise sources. However, panel assembly fabrication may be subject to structural requirements, such as sound-damping and vibration-damping, strength, and/or stiffness requirements, based on overall machine requirements or feature requirements.

### SUMMARY

According to an aspect of the present disclosure, a cover for a housing includes a cast plate-like member having a top side and a bottom side with a plurality of raised ribs on the bottom side, the plurality of raised ribs defining a plurality of spaces therebetween. A noise insulating material and/or a viscous damping material can be provided in at least some of the plurality of spaces. A sheet metal plate is adhered to a top of the plurality of raised ribs by an adhesive or is otherwise secured by a fastener, a bent tab or other fastening mechanisms. The added sheet metal plate adds to the overall stiffness of the structure, and also creates enclosed spaces with or without sound deadening materials.

According to a further aspect of the present invention, a plurality of tabs extend from the plurality of raised ribs and the sheet metal plate includes slits for receiving the plurality of tabs for aligning the sheet metal plate relative to the raised ribs. The plurality of tabs are deformed to further secure the sheet metal plate to the plurality of ribs.

According to a further aspect of the present invention, the plurality of raised ribs include a plurality of screw bosses, and the sheet metal plate is further secured to the plurality of ribs by self-tapping screws engaged with the screw bosses.

According to a further aspect of the present invention, at least one of the plurality of ribs include a depression, wherein the noise insulating material includes a foam or other dampening or sound deadening materials that fill spaces on opposite sides of the at least one of the plurality of ribs.

According to a further aspect of the present invention, a method of making a cover assembly for a housing includes casting a plate-like member having a top side and a bottom side with a plurality of raised ribs on the bottom side, the plurality of raised ribs defining a plurality of spaces therebetween. Noise insulating material is inserted into at least some of the plurality of spaces. An adhesive is applied to a top surface of the plurality of raised ribs and a sheet metal plate is adhered to the plurality of raised ribs.

According to a further aspect, the cover assembly can be cast with a decorative design or logo thereon.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a top plan view of a cover assembly according to the principles of the present disclosure;

FIG. 2 is a bottom plan view of a cast plate-like member of the cover assembly; and

FIG. 3 is a cross-sectional view of the cover assembly taken along line 3-3 of FIG. 1

FIG. 4 is a detailed perspective view showing a tab extending from a raised rib according to the principles of the present disclosure; and

FIG. 5 is detailed perspective view of a screw boss according to the principles of the present disclosure.

In the drawings, reference numbers may be reused to identify similar and/or identical elements.

### DETAILED DESCRIPTION

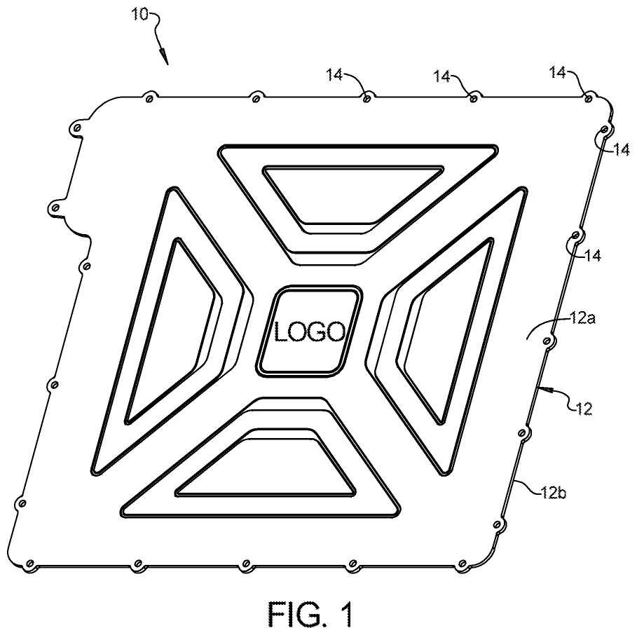

With reference to FIGS. 1-3, a cover 10 for a housing will now be described. The cover 10 includes a plate-like member 12 that can be cast from steel, aluminum, plastic, or other material. The plate-like member 12 include a top side 12a and bottom side 12b. The top side 12a can be formed with, for example, a company logo and other decorative features. An outer perimeter of the plate-like member 12 can include a plurality of mounting apertures 14 configured to receive mounting screws for mounting the cover 10 to a housing.

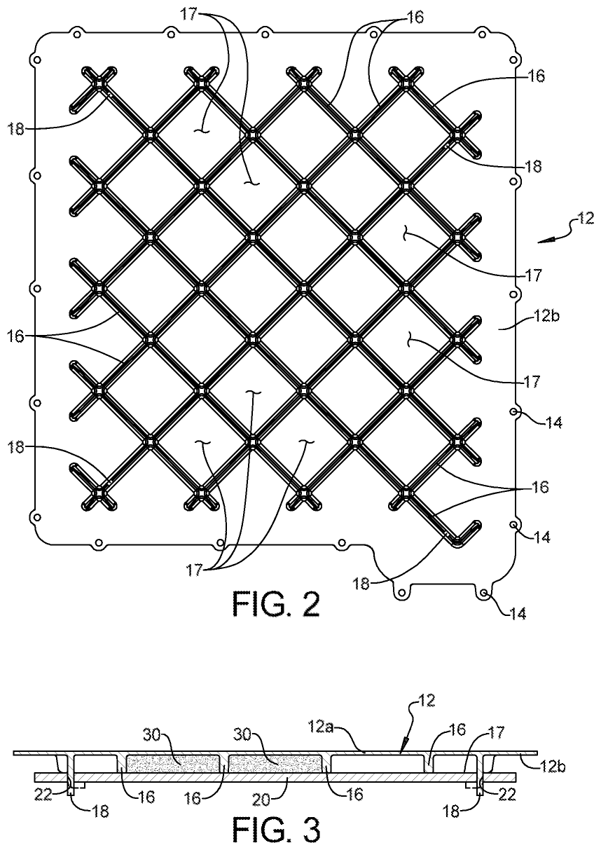

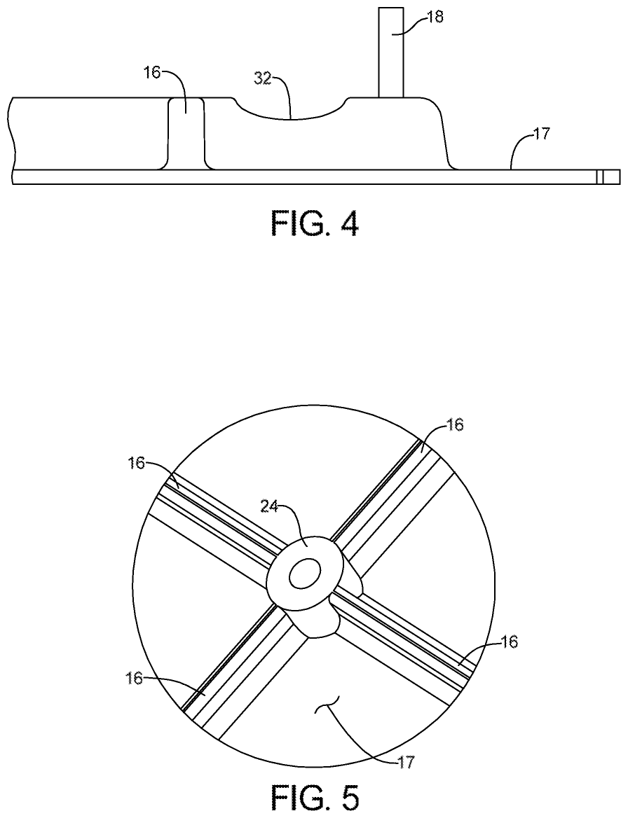

FIG. 2 is a bottom plan view of the plate-like member 12 having a plurality of raised ribs 16. The raised ribs 16 can have a pattern designed to create enclosed areas 17 for noise and vibration reduction in addition to adding rigidity to the plate-like member 12. In the embodiment shown, a diagonal pattern of perpendicular raised ribs 16 are shown. It should be understood however, that other patterns can be used depending upon the shape and the size of the housing and the types of noises and vibrations being mitigated. The location and patterns of the ribs 16 can be strategically optimized to effectively reduce the vibration and noise radiation of the cover 10. A plurality of alignment tabs 18 can extend from the raised ribs 16 at spaced locations, as best shown in FIG. 4.

With reference to FIG. 3, a cross sectional view of the cover is shown with a sheet metal plate 20 adhered to the top of the raised ribs 16 by an adhesive. The sheet metal plate 20 can include a plurality of alignment slits or openings 22 corresponding to the plurality of alignment tabs 18 for aligning the sheet metal plate 20 relative to the plate-like member 12. After the alignment tabs 18 are received through the openings 22, the tabs 18 can be bent over or otherwise deformed to secure the sheet metal plate 20 in place while the adhesive cures or dries. The sheet metal plate closes off the enclosed areas 17 defined by the raised ribs and provides additional noise and vibration mitigation and improved strength the to the cover 10.

As an alternative to the alignment tabs 18, the raised ribs 16 of the plate-like member 12 can include screw bosses 24 formed in the raised ribs 16, as shown in FIG. 5. Mounting screws can be used to secure the sheet metal plate 20 to the plate-like member 12 by engagement with the screw bosses.

A noise insulating material 30 can be inserted in some or all of the enclosed areas 17 defined by the raised ribs 16. The noise insulating material 30 can include foam, felt, various polymers, polymer composites, plastisols, syntactic sound attenuating materials and the like. As shown in FIG. 4, the raised ribs can include one or more depressions 32 that allow a flow of foam or other noise attenuating material 30 to flow therethrough.

A method of making the cover assembly 10 includes casting the plate-like member 12 from metal or plastic. The metal can include aluminum, magnesium or steel. The cast plate-like member 12 can be formed to have a top side and a bottom side with a plurality of raised ribs 16 on the bottom side. The plurality of raised ribs 16 define a plurality of spaces 17 therebetween. Noise insulating material 30 is inserted into at least some of the plurality of spaces. An adhesive 22 is applied to a top surface of the plurality of raised ribs 16 and a sheet metal plate is adhered to the plurality of raised ribs.

The cover assembly 10 can be used as a vehicle panel assembly and may include automotive features, such as a cover for an IPE, an inner panel for a door or a deck lid, a dash panel, a glove box door panel, front-of-trunk panel, a battery tray panel and other interior panels. To reduce the mass of the panel assemblies, a lighter density material may be used, or the cross sectional thickness of the panel assemblies may be reduced. Reducing the mass of the panel assemblies may facilitate reducing the overall weight of the machine or vehicle as a whole. A reduction in the weight of a vehicle, for example, may provide increased efficiency that can be used beneficially in various ways. For example, a reduced weight may increase the range of an electronic vehicle, which may also be translated into cost savings on the battery pack of an electronic vehicle. Light weight metal panels with reduced thickness may have reduced stiffness and damping, and therefore may be an effective conduit for noise sources. However, panel assembly fabrication may be subject to structural requirements, such as sound-damping and vibration-damping, strength, and/or stiffness requirements, based on overall machine requirements or feature requirements.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

What is claimed is:

1. A cover for a housing, comprising:
a cast plate-like member having a top side and a bottom side with a plurality of raised ribs on the bottom side, the plurality of raised ribs defining a plurality of spaces therebetween; and
a sheet metal plate secured to a top of the plurality of raised ribs.

2. The cover according to claim 1, further comprising a plurality of tabs extending from the plurality of raised ribs and the sheet metal plate includes slits for receiving the plurality of tabs.

3. The cover according to claim 2, wherein the plurality of tabs are deformed to further secure the sheet metal plate to the plurality of ribs.

4. The cover according to claim 1, further comprising one of a noise insulating material and a vibration dampening material in at least some of the plurality of spaces.

5. The cover according to claim 1, wherein the plurality of raised ribs include a plurality of screw bosses and the sheet metal plate is further secured to the plurality of ribs by self-tapping screws engaged with the screw bosses.

6. The cover according to claim 4, wherein at least one of the plurality of ribs include a depression, wherein the at least one of a noise insulating material and a vibration dampening material includes a foam that fills spaces on opposite sides of the at least one of the plurality of ribs.

7. The cover according to claim 1, wherein the top surface of the plate-like member includes decorative features formed therein.

8. The cover according to claim 1, wherein the plate-like member includes a plurality of mounting apertures therein.

9. The cover according to claim 1, wherein the sheet metal plate is secured to the top of the plurality of raised ribs by an adhesive.

10. A method of making a cover assembly for a housing, comprising;
casting a plate-like member having a top side and a bottom side with a plurality of raised ribs on the bottom side, the plurality of raised ribs defining a plurality of spaces therebetween;
applying an adhesive to a top surface of the plurality of raised ribs; and
adhering a sheet metal plate to the plurality of raised ribs.

11. The method according to claim 10, further comprising inserting one of a noise insulating material and a vibration dampening material into at least some of the plurality of spaces.

12. The method according to claim 11, wherein the inserting noise insulating material includes injecting a foam into the at least some of the plurality of spaces.

13. The method according to claim 10, wherein the casting a plate-like member includes casting tabs extending from the plurality of raised ribs.

14. The method according to claim 13, wherein the adhering a sheet metal plate to the plurality of raised ribs includes inserting the tabs through slits in the plate-like member and deforming the tabs to secure the sheet metal plate to the plurality of raised ribs.

15. The method according to claim 10, wherein the casting a plate-like member includes casting decorative features on the top side.

16. The method according to claim 10, wherein the plate-like member includes a plurality of mounting apertures therein.
